(19) United States
(12) Patent Application Publication
(10) Pub. No.: US 2026/0211041 A1
(43) Pub. Date: Jul. 23, 2026

(54) DISPLAY SYSTEM

(71) Applicant: TOYOTA JIDOSHA KABUSHIKI KAISHA, Toyota-shi (JP)

(72) Inventor: Yuki SUGO, Seto-shi (JP)

(73) Assignee: TOYOTA JIDOSHA KABUSHIKI KAISHA, Toyota-shi (JP)

(21) Appl. No.: 19/409,910

(22) Filed: Dec. 5, 2025

(30) Foreign Application Priority Data
Jan. 17, 2025 (JP) 2025-006944

(51) Int. Cl. G01R 31/36; G01R 31/367; G01R 31/374; G01R 31/3842; G01R 31/396

(52) U.S. Cl. CPC G01R 31/3646; G01R 31/367; G01R 31/374; G01R 31/3842; G01R 31/396

(57) ABSTRACT

An ECU executes a process including: acquiring, as a subtraction amount ΔC, a maximum SOC variation; acquiring an estimated value of the full charge capacity; acquiring a usable SOC range; subtracting the subtraction amount ΔC from the usable SOC range; calculating a display value of the full charge capacity; and causing the display value of the full charge capacity to be displayed.

### CROSS-REFERENCE TO RELATED APPLICATION

This application claims priority to Japanese Patent Application No. 2025-006944 filed on January 17, 2025. The disclosure of the above-identified application, including the specification, drawings, and claims, is incorporated by reference herein in its entirety.

### BACKGROUND

### Technical Field

The present disclosure relates to display systems.

### Description of Related Art

For example, Japanese Unexamined Patent Application Publication No. 2003-164006 (JP 2003-164006 A) discloses a technique in which the degree of battery degradation is calculated from voltage and current values, the capacity adjustment range is corrected based on the calculated degree of degradation, and the current battery capacity is displayed using segments.

### SUMMARY

When the current capacity of a battery including a plurality of cells is displayed as in the above technique, the state of charge (SOC) may vary between the cells, if an equalization process for aligning the SOC across the cells is not performed for an extended period of time. As a result, the battery capacity cannot be fully utilized, and the actual electric driving range may deviate from the estimated value. Accordingly, the current capacity or full charge capacity of the battery may not be accurately displayed.

The present disclosure has been made to address the above issue, and an object thereof is to provide a display system that accurately displays the battery capacity.

A display system according to one aspect of the present disclosure is configured to display information on a full charge capacity of a battery including a plurality of cells that is lithium iron phosphate cells. The display system includes a display device and a control device. The control device is configured to calculate, as a subtraction amount, a maximum SOC variation between the cells using a charge and discharge history of each of the cells, and subtract the subtraction amount from a usable SOC range of the battery. The display device is configured to display the information on the full charge capacity using a ratio of the usable SOC range minus the subtraction amount to the usable SOC range.

In this configuration, the information on the full charge capacity is displayed using the ratio of the usable SOC range minus the subtraction amount to the usable SOC range. Accordingly, the full charge capacity of the battery can be accurately displayed.

In one embodiment, the control device is configured to detect a step in a change of an open-circuit voltage (OCV) of each of the cells, and calculate the maximum SOC variation using an accumulated amount of current corresponding to variation between the steps of the cells.

With this configuration, the maximum SOC variation can be accurately calculated using the accumulated amount of current corresponding to variation between the steps detected in the respective cells.

In another embodiment, the control device is configured to calculate the maximum SOC variation using variation in a self-discharge amount between the cells over a predetermined period.

With this configuration, the maximum SOC variation can be accurately calculated using variation in the self-discharge amount between the cells.

In still another embodiment, the display device further includes a plurality of monitoring circuits configured to respectively monitor states of the cells. The control device is configured to calculate the maximum SOC variation using variation in power consumption between the monitoring circuits in the cells over a predetermined period.

With this configuration, the maximum SOC variation can be accurately calculated using variation in power consumption between the monitoring circuits in the cells.

In yet another embodiment, the control device is configured to calculate the subtraction amount using, in addition to the charge and discharge history of each of the cells, an SOC range reduced by swelling of the cells.

With this configuration, the full charge capacity of the battery can be more accurately displayed on the display device.

The present disclosure thus provides a display system that accurately displays the battery capacity.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a diagram showing an example of the overall configuration of an electrified vehicle equipped with a display system according to an embodiment of the present disclosure;

FIG. 2 show graphs representing the relationship between the OCV and the remaining capacity, and the relationship between the change ΔVB in voltage VB and the remaining capacity, of a cell according to the embodiment;

FIG. 3 is a flowchart showing an example of a process executed by an electronic control unit (ECU);

FIG. 4 shows graphs representing an example of the relationship between the OCV and the capacity, and the relationship between the accumulated amount of current and the capacity, of multiple cells; and

FIG. 5 is a table showing the relationship among the SOC, temperature, and self-discharge amount of multiple cells.

### DETAILED DESCRIPTION OF EMBODIMENTS

Hereinafter, an embodiment of the present disclosure will be described in detail with reference to the drawings. The same or corresponding parts are denoted by the same signs throughout the drawings, and description thereof will not be repeated.

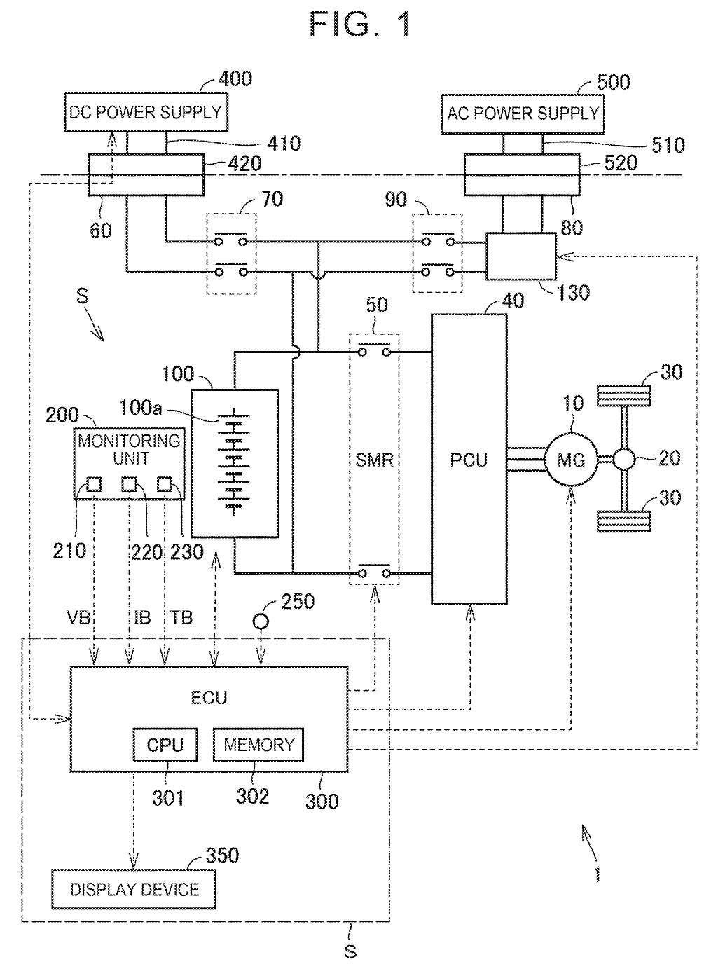

Hereinafter, an example of a display system S according to the present embodiment will be described. FIG. 1 shows an example of the overall configuration of an electrified vehicle 1 equipped with the display system S according to the present embodiment. In the present embodiment, the electrified vehicle 1 may be, for example, a battery electric vehicle. The electrified vehicle 1 includes a motor generator (MG) 10 that is a rotating electrical machine, a power transmission gear 20, drive wheels 30, a power control unit (PCU) 40, a system main relay (SMR) 50, a battery 100, a monitoring unit 200, an electronic control unit (ECU) 300 as an example of the control device, and a display device 350. The ECU 300 and the display device 350 constitute the display system S.

The MG 10 is, for example, an interior permanent magnet synchronous motor (IPM motor), and functions both as an electric motor and as a generator. The output torque of the MG 10 is transmitted to the drive wheels 30 via the power transmission gear 20 that includes a reduction gear and a differential.

During braking of the electrified vehicle 1, the MG 10 is driven by the drive wheels 30 and operates as a generator. Accordingly, the MG 10 also functions as a braking device that performs regenerative braking to convert the kinetic energy of the electrified vehicle 1 into electrical energy. The regenerative power generated by the regenerative braking force of the MG 10 is stored in the battery 100.

The PCU 40 is a power conversion device that bidirectionally converts electric power between the MG 10 and the battery 100. The PCU 40 includes, for example, an inverter and a converter (neither of which is shown) that operate based on control signals from the ECU 300.

When the battery 100 discharges, the converter boosts the voltage supplied from the battery 100 and supplies the boosted voltage to the inverter. The inverter converts the direct current power supplied from the converter into alternating current power to drive the MG 10.

When the battery 100 is charged, the inverter converts the alternating current power generated by the MG 10 into direct current power and supplies the direct current power to the converter. The converter steps down the voltage supplied from the inverter to a level suitable for charging the battery 100 and supplies the resulting voltage to the battery 100.

The SMR 50 is electrically connected to the power line connecting the battery 100 and the PCU 40. When the SMR 50 is closed (ON) in response to a control signal from the ECU 300, electric power can be transferred between the battery 100 and the PCU 40. When the SMR 50 is opened (OFF) in response to a control signal from the ECU 300, the electrical connection between the battery 100 and the PCU 40 is cut off.

The battery 100 stores electric power for driving the MG 10. The battery 100 is a rechargeable direct current power supply (secondary battery) and is configured by stacking a plurality of cells (battery cells) 100a and, for example, electrically connecting the cells 100a in series. Each cell 100a may be, for example, a lithium-ion cell. In the present embodiment, the cells 100a are assumed to be lithium iron phosphate cells (LFP cells) that use lithium iron phosphate as the cathode active material.

The monitoring unit 200 includes a voltage sensor 210, a current sensor 220, and a temperature sensor 230. The voltage sensor 210 detects the voltage VB of each cell 100a (i.e., the voltage VB across the terminals of each cell 100a). The current sensor 220 detects the current IB input to or output from the battery 100 (cells 100a). The current IB may be positive (+) when charging the battery 100 and negative (–) when discharging the battery 100. The temperature sensor 230 detects the temperature TB of each cell 100a. The monitoring unit 200 outputs the detection results from each detection unit to the ECU 300.

The electrified vehicle 1 is equipped with a direct current (DC) inlet 60, and the battery 100 can be fast-charged from an external DC power supply that serves as charging equipment. The DC inlet 60 is configured such that a connector 420 provided at the distal end of a charging cable 410 of an external DC power supply (charging equipment) 400 can be connected to the DC inlet 60. A charging relay 70 is electrically connected to the power line connecting the DC inlet 60 and the battery 100. The charging relay 70 selectively supplies and stops supplying electric power between the DC inlet 60 and the battery 100 in response to a control signal from the ECU 300. When the charging relay 70 is closed, external charging (fast charging) of the battery 100 is performed.

The electrified vehicle 1 is also equipped with an alternating current (AC) inlet 80, and the battery 100 can be normally charged from an external AC power supply that serves as charging equipment. The AC inlet 80 is configured such that a connector 520 provided at the distal end of a charging cable 510 of an external AC power supply (charging equipment) 500 can be connected to the AC inlet 80. An on-board charger 130 is provided on the power line between the AC inlet 80 and the battery 100. The on-board charger 130 converts the alternating current power supplied from the external AC power supply into direct current power, and further converts the direct current power to a voltage that can charge the battery 100. A charging relay 90 is electrically connected to the power line connecting the on-board charger 130 and the battery 100. The charging relay 90 selectively supplies and stops supplying electric power between the on-board charger 130 and the battery 100 in response to a control signal from the ECU 300. When the charging relay 90 is closed, external charging (normal charging) of the battery 100 is performed.

The ECU 300 includes a central processing unit (CPU) 301 and a memory 302 (including, for example, read-only memory (ROM) and random access memory (RAM)). The ECU 300 controls each device such that the electrified vehicle 1 attains a desired state, based on signals received from the monitoring unit 200, signals from various sensors (not shown) (such as an accelerator operation amount signal and a vehicle speed signal), and information such as maps and programs stored in the memory 302. The ECU 300 also executes processes such as estimation of the full charge capacity.

The display device 350 is configured to present text information as visual messages to the user of the electrified vehicle 1 in response to control commands from the ECU 300. The display device 350 may be constituted by, for example, a display unit of a touch panel display provided near the driver's seat. The display unit may be, for example, a liquid crystal display (LCD) or an organic electroluminescence (EL) display. The display device 350 may be provided in a combination meter (not shown) that can be viewed by the user of the electrified vehicle 1 when seated in the driver's seat.

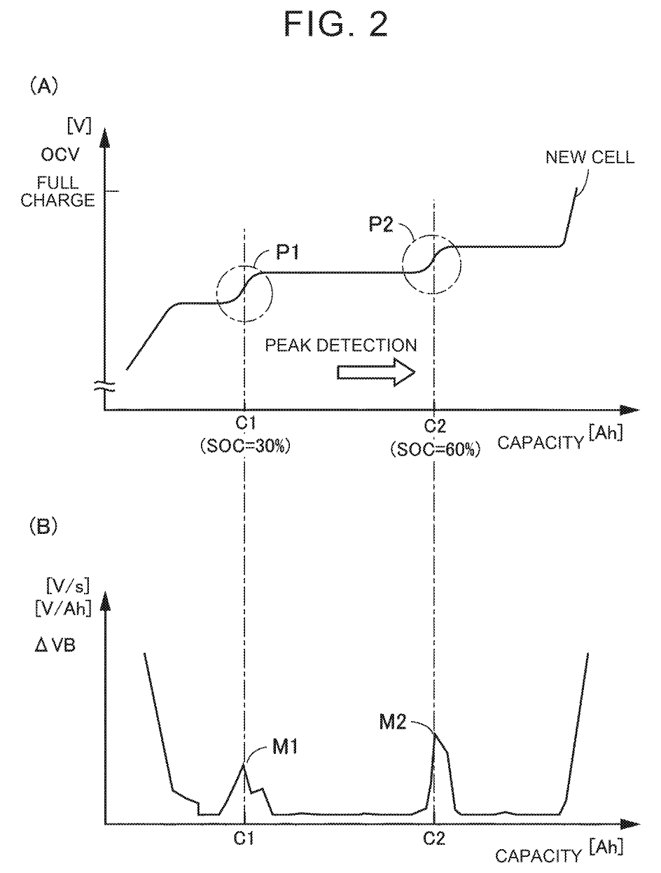

FIG. 2 shows graphs representing the relationship between the open-circuit voltage (OCV) and the remaining capacity, and the relationship between the change ΔVB in voltage VB and the remaining capacity, of the cell 100a (LFP cell) of the present embodiment. In part (A) of FIG. 2, the vertical axis represents the OCV (V) of the cell 100a, and the horizontal axis represents the remaining capacity (charge capacity) (Ah) of the cell 100a. As shown in part (A) of FIG. 2, in the relationship between the OCV and the remaining capacity (hereinafter also referred to as the "OCV curve"), there is a broad region where the OCV curve shows little change (a flat voltage region). When a portion of the OCV curve that rises from a flat voltage region and then transitions into another flat voltage region is referred to as a "step," there are two steps P1, P2 in the cell 100a of the present embodiment.

In a new cell 100a, the first step P1 (on the lower-voltage side of the OCV curve) appears at an SOC of around 30%, and the second step P2 (on the higher-voltage side of the OCV curve) appears at an SOC of around 60%.

Part (B) of FIG. 2 shows the relationship between the change ΔVB in the voltage VB and the remaining capacity during charging of the battery 100. This relationship represents the case where the battery 100 is charged or discharged at a constant current. The voltage change ΔVB represents the rate of change in the voltage VB with respect to the remaining capacity (charge capacity) (V/Ah), or the rate of change in the voltage VB with respect to time (charging time or discharging time) (V/s). As shown in part (B) of FIG. 2, the voltage change ΔVB reaches a peak value M1 at the remaining capacity corresponding to the step P1, and a peak value M2 at the remaining capacity corresponding to the step P2. Accordingly, the full charge capacity of the battery 100 (cell 100a) can be estimated by storing the remaining capacity at which the voltage change ΔVB reaches the peak value M2 as a reference capacity C2, accumulating the charging current from when the voltage change ΔVB reaches the peak value M2 until the battery is fully charged, and adding the accumulated value to the reference capacity C2.

Since the battery 100 includes the plurality of cells 100a, the SOC may vary between the cells 100a. In such a case, an equalization process is performed to bring the battery 100, and therefore, each cell 100a, to a fully charged state so as to reduce or eliminate such SOC variation. However, if the equalization process is not performed for an extended period of time, the SOC variation between the cells may increase, and as a result, the capacity of the battery 100 may not be fully utilized, causing the actual electric driving range to deviate from the estimated value. Accordingly, the current capacity or full charge capacity of the battery 100 may not be accurately displayed.

Accordingly, in the present embodiment, the ECU 300 calculates, as a subtraction amount ΔC(0), the maximum SOC variation between the cells 100a using the charge and discharge history of each cell 100a. The ECU 300 then subtracts the subtraction amount ΔC(0) from the usable SOC range of the battery 100, and displays information on the full charge capacity using the ratio of the usable SOC range minus the subtraction amount ΔC(0) to the usable SOC range.

As described above, information on the full charge capacity is displayed using the ratio of the usable SOC range minus the subtraction amount to the usable SOC range. Accordingly, the full charge capacity of the battery 100 can be accurately displayed.

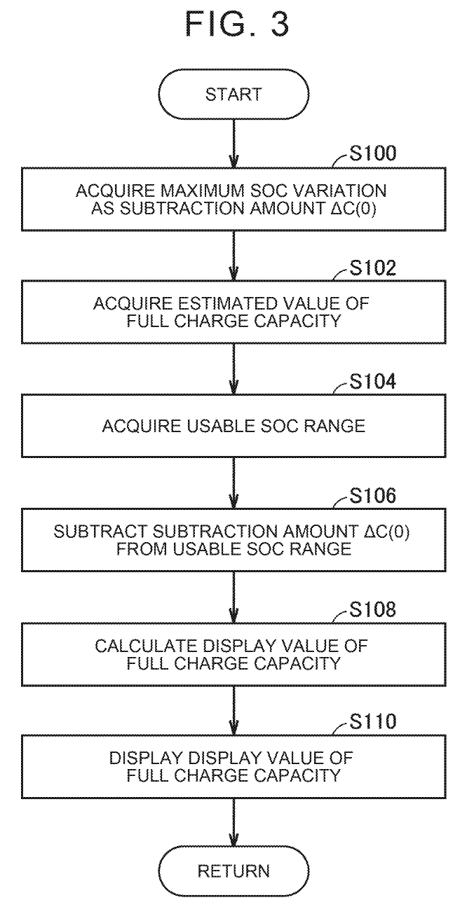

An example of the process executed by the ECU 300 will now be described with reference to FIG. 3. FIG. 3 is a flowchart showing an example of the process executed by the ECU 300. For example, when the connector 420 is connected to the DC inlet 60 or the connector 520 is connected to the AC inlet 80, external charging of the battery 100 starts. Once external charging of the battery 100 starts, the process shown in the flowchart is executed.

In step 100 (hereinafter the term "step" will be abbreviated as "S"), the ECU 300 acquires the maximum SOC variation between the cells 100a as the subtraction amount ΔC(0). More specifically, the ECU 300 detects the steps of each cell 100a. For example, the ECU 300 detects the step P2 by detecting the peak value corresponding to the second step P2 (on the higher-voltage side) of the OCV curve.

That is, the ECU 300 may calculate the OCV change ΔOCV, and may determine that a peak value has been detected when the current ΔOCV(n) is smaller than the previous ΔOCV(n–1). Alternatively, the ECU 300 may determine that a peak value has been detected when the sign of the derivative of ΔOCV changes from positive to negative. For example, the ECU 300 starts accumulating current from the time when the step P2 is first detected in any of the cells 100a. The ECU 300 calculates the amount of current accumulated up to the time when the step P2 is last detected in any of the cells 100a. The ECU 300 calculates the maximum SOC variation as the subtraction amount ΔC(0) from the accumulated amount of current. For example, a map representing the relationship between the accumulated amount of current and the subtraction amount ΔC(0) may be set in advance through experiments or the like and stored in the memory 302, and the ECU 300 may calculate the subtraction amount ΔC(0) using the accumulated amount of current and the map. The map may include battery temperature in addition to the accumulated amount of current and the subtraction amount ΔC(0).

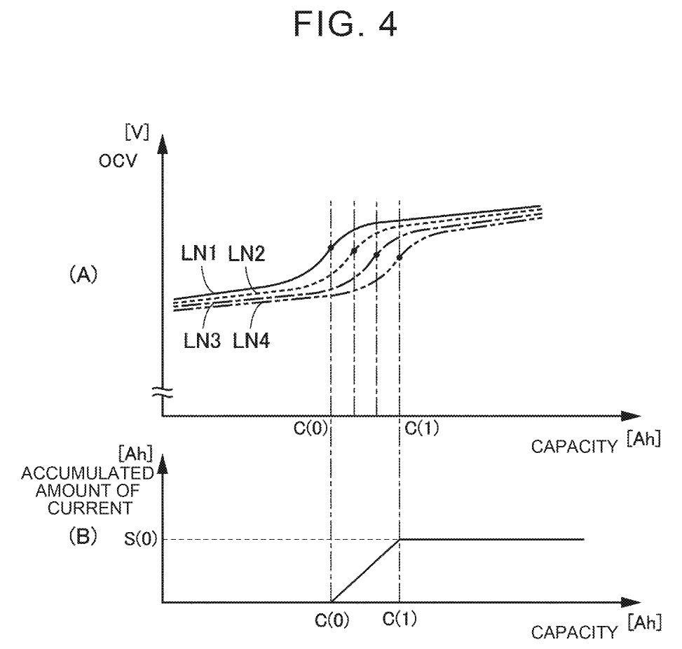

FIG. 4 shows graphs representing an example of the relationship between the OCV and the capacity, and the relationship between the accumulated amount of current and the capacity, of multiple cells 100a. In part (A) of FIG. 4, the vertical axis represents the OCV, and the horizontal axis represents the capacity. In part (B) of FIG. 4, the vertical axis represents the accumulated amount of current, and the horizontal axis represents the capacity. Part (A) of FIG. 4 shows an example of the relationship between the OCV and the capacity of four of the cells 100a. In part (A) of FIG. 4, LN1, LN2, LN3, and LN4 show examples of the relationship between the OCV and the capacity of first, second, third, and fourth cells, respectively. In the following description, FIG. 4 is taken as an example in which LN1 corresponds to the first cell in which a step is first detected, and LN4 corresponds to the fourth cell in which a step is last detected.

As shown in LN1 of part (A) of FIG. 4, when a peak value is detected in the change of the OCV of the first cell among the multiple cells 100a during external charging, current accumulation is started as shown in part (B) of FIG. 4. As shown in LN2 and LN3 of part (A) of FIG. 4, the current accumulation is continued when peak values are detected in the changes of the OCV of the second and third cells. Then, as shown in LN4 of part (A) of FIG. 4, when a peak value is detected in the change of the OCV of the fourth cell, the current accumulation is stopped, and the accumulated amount of current S(0) is calculated, as shown in part (B) of FIG. 4. The ECU 300 then calculates the subtraction amount ΔC(0) using the accumulated amount of current S(0) and the map. The process then proceeds to S102.

In S102, the ECU 300 acquires an estimated value of the full charge capacity. The ECU 300 may acquire the estimated value of the full charge capacity from, for example, the monitoring unit 200. For example, the monitoring unit 200 calculates the estimated value of the full charge capacity during the most recent charging event of the battery 100, based on the OCV(1) at the start of charging, the OCV(2) at the end of charging, and the charging current accumulated between the start and the end of charging. Specifically, the monitoring unit 200 calculates the estimated value of the full charge capacity from, for example, the SOC change ΔSOC obtained from the difference between OCV(1) and OCV(2), and the change in capacity obtained from the accumulated charging current. Alternatively, the ECU 300 may calculate the estimated value of the full charge capacity. The process then proceeds to S104.

In S104, the ECU 300 acquires the usable SOC range. For example, the usable SOC range is calculated by subtracting the SOC at which driving of the electrified vehicle 1 is ended from the SOC corresponding to the fully charged state (95%). The SOC at which driving of the electrified vehicle 1 is ended is a predetermined value. The usable SOC range may be a predetermined value and stored in the memory 302 of the ECU 300, may be acquired from a storage device (not shown) of the monitoring unit 200, or may be acquired from an external server. The process then proceeds to S106.

In S106, the ECU 300 subtracts the subtraction amount ΔC(0) from the usable SOC range. The process then proceeds to S108.

In S108, the ECU 300 calculates a display value of the full charge capacity. Specifically, the ECU 300 calculates the ratio of the usable SOC range minus the subtraction amount ΔC(0) to the usable SOC range. That is, the ECU 300 calculates the ratio by dividing the usable SOC range minus the subtraction amount ΔC(0) by the usable SOC range. The ECU 300 then calculates the display value of the full charge capacity (a corrected value of the capacity retention rate) by multiplying the current capacity retention rate by the calculated ratio. The ECU 300 may calculate the current capacity retention rate by, for example, dividing the estimated value of the full charge capacity by the initial full charge capacity. The initial full charge capacity is the full charge capacity when no battery degradation has occurred. The initial full charge capacity may be a value determined in advance according to the type of the battery 100 and stored in the memory 302 of the ECU 300, may be acquired from the storage device (not shown) of the monitoring unit 200, or may be acquired from an external server. The process then proceeds to S110.

In S110, the ECU 300 causes the display device 350 to display the calculated display value of the full charge capacity. The process then ends.

The operation of the ECU 300 based on the above structure and flowchart will now be described. For example, when the connector 420 is connected to the DC inlet 60, external charging of the battery 100 is started.

When external charging of the battery 100 is started, the ECU 300 acquires the maximum SOC variation between the cells 100a as the subtraction amount ΔC(0) (S100). As described above, the ECU 300 detects the steps of each cell 100a. Current accumulation starts from the time when a step is first detected, and continues until the time when a step is last detected. The maximum SOC variation is calculated as the subtraction amount ΔC(0) using the amount of current accumulated during that period.

Thereafter, the ECU 300 acquires an estimated value of the full charge capacity of the battery 100 from the monitoring unit 200 (S102), and also acquires the usable SOC range of the battery 100 (S104).

The ECU 300 subtracts the subtraction amount ΔC(0) from the usable SOC range of the battery 100 (S106), and multiplies the current capacity retention rate by the ratio of the usable SOC range minus the subtraction amount ΔC(0) to the usable SOC range to calculate the display value of the full charge capacity (S108). The ECU 300 then causes the display device 350 to display the calculated display value (S110).

As described above, in the display system S of the present embodiment, the current capacity retention rate is corrected using the subtraction amount ΔC(0), namely the maximum SOC variation between the cells 100a. The full charge capacity of the battery 100 can thus be accurately displayed. Accordingly, it is possible to provide a display device that accurately displays the battery capacity.

Furthermore, the maximum SOC variation can be accurately calculated using the accumulated amount of current corresponding to the steps detected in each cell 100a.

Modifications will now be described.

The above embodiment illustrates an example in which the maximum SOC variation is calculated using the accumulated amount of current. However, the present disclosure is not particularly limited to the use of the accumulated amount of current. For example, the ECU 300 may calculate the maximum SOC variation using the self-discharge amount of each cell 100a when left unused.

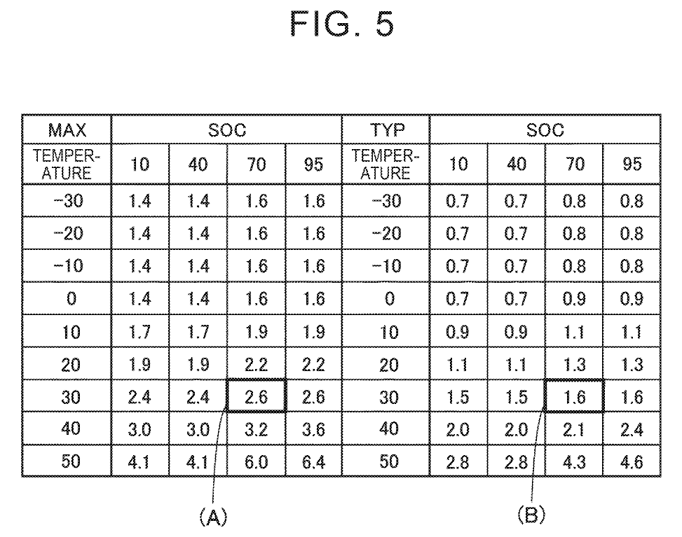

FIG. 5 is a table showing the relationship among the SOC, temperature, and self-discharge amount of the cells 100a. FIG. 5 shows the self-discharge amounts corresponding to various SOCs and temperatures when charging to a fully charged state is not performed for a predetermined number of days (for example, 30 days). The left side of FIG. 5 shows the maximum error (MAX) (%) of the self-discharge amounts corresponding to various SOCs and temperatures of the cells 100a. The right side of FIG. 5 shows the average error (TYP) (%) of the self-discharge amounts corresponding to various SOCs and temperatures of the cells 100a. The SOCs herein include, but are not limited to, 10%, 40%, 70%, and 95%. The temperatures herein include, but are not limited to, −30°C, −20°C, −10°C, 0°C, 10°C, 20°C, 30°C, 40°C, and 50°C. After the battery has been fully charged, the ECU 300 acquires the self-discharge amount of each cell 100a. For example, until the next charging is performed, the ECU 300 acquires the self-discharge amount of each cell 100a corresponding to its SOC and temperature, on condition that the SOC and temperature remain constant for a predetermined period. When the period until the next charging has reached a predetermined number of days, the ECU 300 updates the self-discharge amounts corresponding to the various SOCs and temperatures shown in FIG. 5 using the acquired self-discharge amounts. That is, the ECU 300 calculates the maximum error and the average error of the self-discharge amounts using the acquired self-discharge amounts, and updates the self-discharge amounts corresponding to the various SOCs and temperatures shown in FIG. 5.

For example, the ECU 300 may extract the maximum error and the average error of the self-discharge amount at the same SOC and the same temperature, calculate the difference therebetween, and calculate the maximum SOC variation using the calculated difference. Specifically, for example, the ECU 300 extracts a maximum error of 2.6% in the self-discharge amount at an SOC of 70% and a temperature of 30°C as shown in (A) of FIG. 5, and extracts an average error of 1.6% in the self-discharge amount at the same SOC (70%) and temperature (30°C) as shown in (B) of FIG. 5. The ECU 300 then calculates the maximum SOC variation using the difference of 1% between the extracted values. For example, a map representing the relationship between the difference and the maximum SOC variation may be set in advance, and the ECU 300 may calculate the maximum SOC variation using the calculated difference and this map. In this way as well, the maximum SOC variation can be calculated accurately.

The above embodiment illustrates an example in which the maximum SOC variation is calculated using the accumulated amount of current. However, the present disclosure is not particularly limited to the use of the accumulated amount of current. For example, the ECU 300 may calculate the maximum SOC variation using variation in power consumption between monitoring integrated circuits (ICs). The monitoring unit 200 includes a plurality of monitoring ICs. The monitoring ICs monitor the states (current, voltage, and temperature) of the cells 100a. The monitoring ICs are configured to operate using the power of the respective cells 100a. The ECU 300 acquires the power consumption of the monitoring ICs. For example, the ECU 300 calculates the difference between the maximum error and the average error of the amount of power consumption of each monitoring IC over a predetermined number of days (e.g., 30 days). The ECU 300 may then calculate the maximum SOC variation using the calculated difference. For example, a map representing the relationship between the difference and the maximum SOC variation may be set in advance, and the ECU 300 may calculate the maximum SOC variation using the calculated difference and the map. In this way as well, the maximum SOC variation can be accurately calculated.

The above embodiment illustrates an example in which the maximum SOC variation is calculated as the subtraction amount ΔC(0), and the subtraction amount ΔC(0) is subtracted from the usable SOC range to calculate the ratio of the usable SOC range minus the subtraction amount ΔC(0) to the usable SOC range. However, the correction is not particularly limited to this method. For example, the ECU 300 may subtract, from the usable SOC range, the subtraction amount ΔC(0) and the SOC range reduced due to swelling of the battery 100. The SOC range reduced due to swelling may be a predetermined value, or may be set according to the degradation state of the cells 100a. In this way, the full charge capacity of the battery 100 can be displayed more accurately.

Part or all of the above modifications may be combined as appropriate.

The embodiment disclosed herein should be construed as illustrative in all respects and not restrictive. The scope of the present disclosure is set forth in the claims rather than in the above description, and is intended to include all modifications within the meaning and scope equivalent to the claims.

What is claimed is:

1. A display system configured to display information on a full charge capacity of a battery including a plurality of cells that is lithium iron phosphate cells, the display system comprising:
a display device; and
a control device, wherein:
the control device is configured to calculate, as a subtraction amount, a maximum state-of-charge variation between the cells using a charge and discharge history of each of the cells, and subtract the subtraction amount from a usable state-of-charge range of the battery; and
the display device is configured to display the information on the full charge capacity using a ratio of the usable state-of-charge range minus the subtraction amount to the usable state-of-charge range.

2. The display system according to claim 1, wherein the control device is configured to detect a step in a change of an open-circuit voltage of each of the cells, and calculate the maximum state-of-charge variation using an accumulated amount of current corresponding to variation between the steps of the cells.

3. The display system according to claim 1, wherein the control device is configured to calculate the maximum state-of-charge variation using variation in a self-discharge amount between the cells over a predetermined period.

4. The display system according to claim 1, further comprising a plurality of monitoring circuits configured to respectively monitor states of the cells,
wherein the control device is configured to calculate the maximum state-of-charge variation using variation in power consumption between the monitoring circuits in the cells over a predetermined period.

5. The display system according to claim 1, wherein the control device is configured to calculate the subtraction amount using, in addition to the charge and discharge history of each of the cells, a state-of-charge range reduced by swelling of the cells.
